(19) United States
(12) Patent Application Publication
(10) Pub. No.: US 2023/0098767 A1
(43) Pub. Date: Mar. 30, 2023

(54) Optical Sensing Device

(71) Applicant: InnoLux Corporation, Miao-Li County (TW)

(72) Inventors: Wei-Lin WAN, Miao-Li County (TW); Yu-Tsung LIU, Miao-Li County (TW); Te-Yu LEE, Miao-Li County (TW)

(73) Assignee: InnoLux Corporation, Miao-Li County (TW)

(21) Appl. No.: 17/896,099

(22) Filed: Aug. 26, 2022

(30) Foreign Application Priority Data
Sep. 26, 2021 (CN) 202111128800.8

(51) Int. Cl. G01J 1/04; H01L 27/144; G01J 1/42

(52) U.S. Cl. CPC G01J 1/0437; H01L 27/1446; H01L 27/1443; G01J 1/42

(57) ABSTRACT

An optical sensing device includes a substrate; a light-sensing element disposed on the substrate; a light-shielding layer disposed on the light-sensing element, including a first opening overlapping the light-sensing element; an insulating layer disposed on the light-shielding layer, including a second opening overlapping the first opening; a light-shielding element disposed on a hole wall of the second opening; and a light-collecting element disposed on the insulating layer and overlapping the second opening.

### CROSS REFERENCE TO RELATED APPLICATION

This application claims the benefit of China Patent Application No. 202111128800.8, filed on Sep. 26, 2021, the entire content of which is incorporated herein by reference.

### BACKGROUND OF THE DISCLOSURE

### 1. Field of the Disclosure

The present disclosure relates to an optical sensing device, and more particularly to an optical sensing device for collimating a light.

### 2. Description of the Prior Art

An optical sensing device may adjust a direction of a light via a light collimating structure, e.g., adjust a stray light (e.g., a reflected light or other lights which does not come from a light source) to a collimated light. In general, the light collimating structure may be an array structure, which may include multi-layer aperture layers. In the existing optical sensing device manufacturing processes, the multi-layer aperture layers may be fabricated via a multi-layer film, to form a distance needed for a lens to focus. However, a thick film is usually fabricated via an organic material, which not only requires high material costs, but also involves complicated manufacturing processes.

### SUMMARY OF THE DISCLOSURE

The present disclosure therefore provides an optical sensing device for collimating a light to solve the abovementioned problem.

The present disclosure provides an optical sensing device. The optical sensing device includes a substrate; a light-sensing element disposed on the substrate; a light-shielding layer disposed on the light-sensing element, comprising a first opening overlapping the light-sensing element; an insulating layer disposed on the light-shielding layer, comprising a second opening overlapping the first opening; a light-shielding element disposed on a hole wall of the second opening; and a light-collecting element disposed on the insulating layer and overlapping the second opening.

The present disclosure further provides an optical sensing device. The optical sensing device includes a substrate; a light-sensing element disposed on the substrate; a light-shielding layer disposed on the light-sensing element, comprising a first opening overlapping the light-sensing element; an insulating layer disposed on the light-shielding layer, comprising a second opening overlapping the first opening; and a light-collecting element disposed on the insulating layer, and at least one part of the light-collecting element is located in the second opening; wherein a first refractive index of the insulating layer is greater than a second refractive index of the light-collecting element.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic diagram of an optical sensing device according to some embodiments of the present disclosure.

FIG. 2 is a schematic diagram of an optical sensing device according to some embodiments of the present disclosure.

FIG. 3 is a schematic diagram of an optical sensing device according to some embodiments of the present disclosure.

FIG. 4 is a schematic diagram of an optical sensing device according to some embodiments of the present disclosure.

FIG. 5 is a schematic diagram of a light-collecting element for calculating a radius of curvature of a spherical mirror according to some embodiments of the present disclosure.

FIG. 6 is a schematic diagram of an optical sensing device according to some embodiments of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of a display device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function.

In the following description and in the claims, the terms “include”, “comprise” and “have” are used in an open-ended fashion, and thus should be interpreted to mean “include, but not limited to . . . ”.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

It will be understood that, when the corresponding component such as layer or area is referred to “on another component”, it may be directly on this another component, or other component(s) may exist between them (indirect case). On the other hand, when the component is referred to “directly on another component (or the variant thereof)”, any component does not exist between them. “electrically connected to” another element or layer can be directly electrically connected to the other element or layer, or intervening elements or layers may be presented. The terms of “jointed” and “connected” may also include cases where both structures are movable or both structures are fixed.

The terms “equal”, or “same” generally mean within 20% of a given value or range, or mean within 10%, 5%, 3%, 2%, 1%, or 0.5% of a given value or range. According to an optical microscopy (OM) or a scanning electron microscope (SEM), a given value or a range may be measured or observed.

The term “in a range from a first value to a second value” means the range includes the first value, the second value, and other values in between.

Although terms such as first, second, third, etc., may be used to describe diverse constituent elements, such constituent elements are not limited by the terms. These terms are used only to discriminate a constituent element from other constituent elements in the specification, and these terms have no relation to the manufacturing order of these constituent components. The claims may not use the same terms, but instead may use the terms first, second, third, etc. with respect to the order in which an element is claimed. Accordingly, in the following description, a first constituent element may be a second constituent element in a claim.

It is noted that the technical features in different embodiments described in the following can be replaced, recombined or mixed with one another to constitute another embodiment without departing from the spirit of the present disclosure.

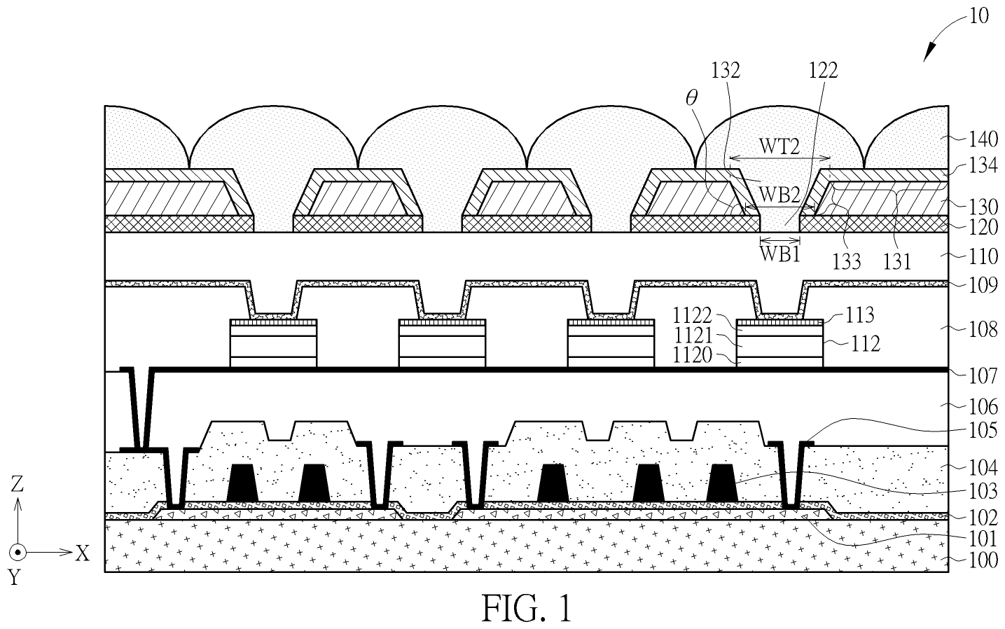

FIG. 1 is a schematic diagram of an optical sensing device 10 according to some embodiments of the present disclosure. As shown in FIG. 1, X axis, Y axis and Z axis are perpendicular to each other, wherein the Z axis is a normal direction of a substrate 100. The optical sensing device 10 may include a substrate 100, a first semiconductor layer 101, a first insulating layer 102, a first conductive layer 103, a second insulating layer 104, a second conductive layer 105, a third insulating layer 106, a third conductive layer 107, a fourth insulating layer 108, a fourth conductive layer 109, a fifth insulating layer 110, a light-sensing element 112, a fifth conductive layer 113, a light-shielding layer 120, a sixth insulating layer 130, a light-shielding element 134 and a light-collecting element 140.

In some embodiments, at least apart of the first semiconductor layer 101, at least a part of the first conductive layer 103 and at least a part of the second conductive layer 105 may form a thin film transistor (TFT). In some embodiments, the light-sensing element 112 may be electrically connected to the TFT via the third conductive layer 107. In some embodiments, different light-sensing elements 112 may be electrically connected to each other via the fourth conductive layer 109 and the fifth conductive layer 113.

As shown in FIG. 1, the light-sensing element 112 may be disposed on the substrate 100. The light-shielding layer 120 may be disposed on the light-sensing element 112, and may include a first opening 122 overlapping the light-sensing element 112. The first opening 122 may be formed by coating a material via a photolithography process, or may be formed by patterning via the photolithography process and an etching after depositing the material, but is not limited thereto. The sixth insulating layer 130 may be disposed on the light-shielding layer 120, and may include a second opening 132 overlapping the first opening 122. The second opening 132 may be formed by coating a material via a photolithography process, or may be formed by patterning via the photolithography process and an etching after depositing the material, but is not limited thereto. The light-shielding element 134 may be disposed on the sixth insulating layer 130. The light-collecting element 140 may be disposed on the sixth insulating layer 130. The light-collecting element 140 may overlap the second openings 132. The first openings 122 may include regions between the light-shielding layers 120. The second openings 132 may include regions between the sixth insulating layers 130.

In this embodiment, a stray light (e.g., a reflected light or other lights which does not come from a light source) may be absorbed by or reflected via disposing the light-shielding element 134 on the sixth insulating layer 130, to block interference of the stray light.

In some embodiments, the light-shielding element 134 may be disposed on an upper surface 131 of the sixth insulating layer 130, and at least a part of the light-shielding element 134 may be located in the second opening 132. In some embodiments, at least a part of the light-shielding element 134 may be disposed on a hole wall 133 of the second opening 132. For example, the hole wall 133 of the second opening 132 may include a region from the top of the sixth insulating layer 130 (e.g., from where a curvature of a surface changes) to the bottom of the sixth insulating layer 130.

In some embodiments, at least a part of the light-collecting element 140 may be located in the second opening 132. In some embodiments, at least a part of the light-collecting element 140 may be located in the first opening 122.

In some embodiments, the light-collecting element 140 may overlap the same pixel or different pixels. In some embodiments, the light-collecting element 140 may overlap the same sub-pixel or different sub-pixels. In some embodiments, an overlap may include completely overlap or partial overlap.

It is noted that, for purposes of illustrative clarity and being easily understood by the readers, materials for each layer and/or element are recited after the figures.

In some embodiments, the light-shielding element 134 may include a light-absorbent material. In some embodiments, the light-shielding element 134 may include a reflecting material.

In some embodiments, the light-shielding layer 120 and the light-shielding element 134 may include the same material. For example, both the light-shielding layer 120 and the light-shielding element 134 may include the light-absorbent material, or both the light-shielding layer 120 and the light-shielding element 134 may include the reflecting material. In some embodiments, the light-shielding layer 120 and the light-shielding element 134 may include different materials. For example, the light-shielding layer 120 may include the reflecting material and the light-shielding element 134 may include the light-absorbent material, or the light-shielding layer 120 may include the light-absorbent material and the light-shielding element 134 may include the reflecting material.

In some embodiments, the first opening 122 may have a first bottom width WB1 located at the bottom of the first opening 122 (i.e., a side close to the substrate 100) in a cross-sectional direction, and the second opening 132 may have a second bottom width WB2 and a second top width WT2 located at the bottom of the second opening 132 (i.e., the side close to the substrate 100) and the top of the second opening 132 (i.e., a side away from the substrate 100), respectively, in the cross-sectional direction. In some embodiments, the first bottom width WB1 may be smaller than the second bottom width WB2. In some embodiments, the first bottom width WB1 may be equal to the second bottom width WB2. In some embodiments, the second bottom width WB2 may be smaller than the second top width WT2. In some embodiments, the second bottom width WB2 may be equal to the second top width WT2.

In this embodiment, the light-shielding element 134 may be disposed on the upper surface 131 of the sixth insulating layer 130 and the hole wall 133 of the second opening 132. In addition, in this embodiment, the first bottom width WB1 may be equal to the second bottom width WB2 and the second bottom width WB2 may be smaller than the second top width WT2. That is, the closer to the substrate 100, the smaller the width of the second opening 132 is. The hole wall 133 of the second opening 132 and the substrate 100 may form an included angle θ which is smaller than 90 degrees. This design may absorb or reflect more stray lights in different paths. In different embodiments, it also may have the same technical feature without departing from the spirit of the present disclosure.

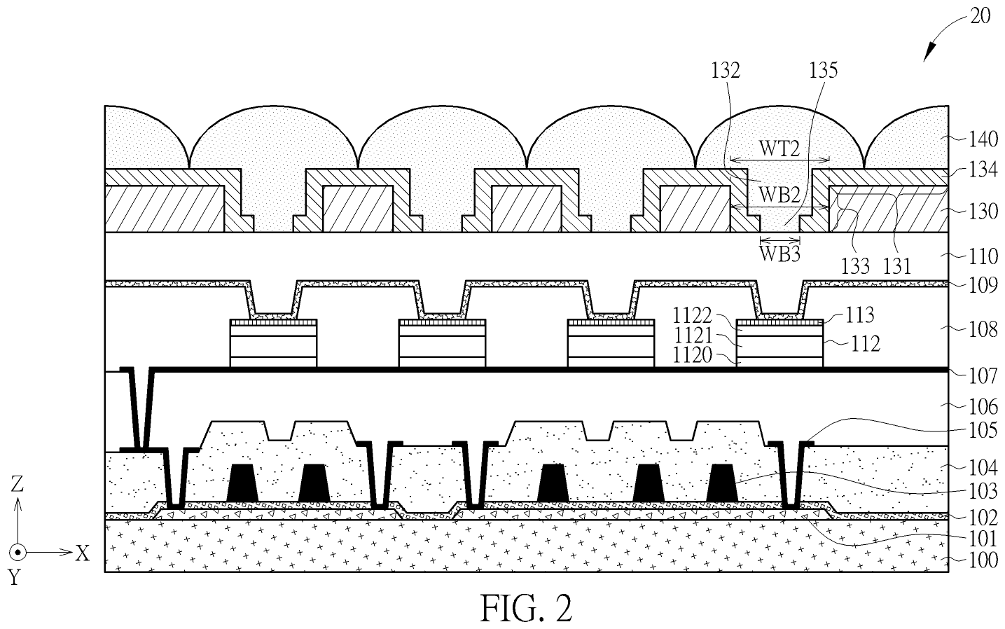

FIG. 2 is a schematic diagram of an optical sensing device 20 according to some embodiments of the present disclosure. Compared with the optical sensing device 10 in FIG. 1, the optical sensing device 20 may not include the light-shielding layer 120. The light-shielding element 134 may include the light-absorbent material or the reflecting material, but is not limited thereto. As shown in FIG. 2, along the Z axis, the hole wall 133 of the second opening 132 may include a region from the top of the sixth insulating layer 130 (e.g., from where a curvature of a surface changes) to the bottom of the sixth insulating layer 130. The light-shielding element 134 may be disposed on the upper surface 131 of the sixth insulating layer 130 and the hole wall 133 of the second opening 132. In addition, the light-shielding element 134 may be disposed on the fifth insulating layer 110, which may include a third opening 135 overlapping the second opening 132, and the third opening 135 may have a third bottom width WB3.

In this embodiment, a stray light (e.g., a reflected light or other lights which does not come from a light source) may be absorbed by or reflected by disposing the light-shielding element 134 on the sixth insulating layer 130, to block interference of the stray light.

In addition, the second bottom width WB2 may be equal to the second top width WT2. That is, the entire (e.g., the top and the bottom) widths of the second opening 132 are equal, and the second bottom width WB2 may be greater than the third bottom width WB3, such that the width of the opening close to the substrate 100 is smaller, which may absorb or reflect more stray lights in different paths. In different embodiments, it also may have the same technical feature without departing from the spirit of the present disclosure.

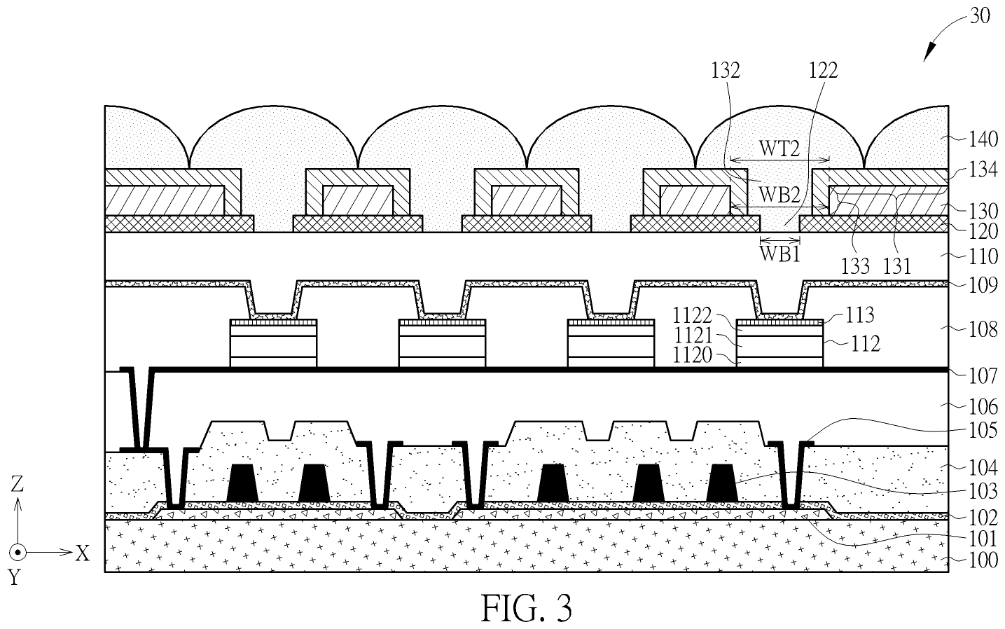

FIG. 3 is a schematic diagram of an optical sensing device 30 according to some embodiments of the present disclosure. Compared with the optical sensing device 10 in FIG. 1, the second bottom width WB2 may be equal to the second top width WT2. That is, the entire (e.g., the top and the bottom) widths of the second opening 132 are equal, and the second bottom width WB2 may be greater than the first bottom width WB1, such that the width of the opening close to the substrate 100 is smaller, which may absorb or reflect more stray lights indifferent paths. In different embodiments, it also may have the same technical feature without departing from the spirit of the present disclosure.

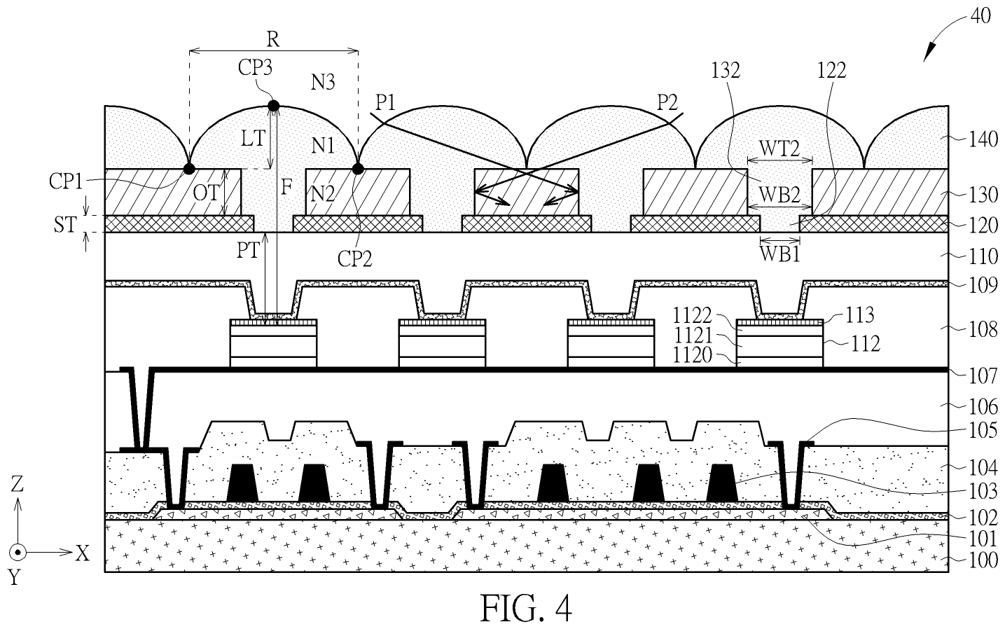

FIG. 4 is a schematic diagram of an optical sensing device 40 according to some embodiments of the present disclosure. Compared with the optical sensing device 10 in FIG. 1, the optical sensing device 40 may not include the light-shielding element 134, the light-collecting element 140 may have a first refractive index N1 and the sixth insulating layer 130 may have a second refractive index N2. An external medium of the light-collecting element 140 facing a user (e.g., an air medium or a material around the light-collecting element 140) may have a third refractive index N3. In this embodiment, the first refractive index N1 of the light-collecting element 140 may be in a range from 1.4 to 1.65 (1.4≤N1≤1.65); The second refractive index N2 of the sixth insulating layer 130 may be greater than 1.7; The third refractive index N3 of the external medium may be in a range from 1 to 1.2 (1≤N3≤1.2).

As shown in FIG. 4, according to a first light path P1 and a second light path P2, when the second refractive index N2 of the sixth insulating layer 130 is greater than the first refractive index N1 of the light-collecting element 140 and when a light is from an optically denser medium (e.g., the sixth insulating layer 130) to an optically thinner medium (e.g., the light-collecting element 140), the light is totally reflected in a medium of higher refractive index and a possibility of the light passing through the sixth insulating layer 130 to other elements is reduced. That is, a stray light (e.g., a reflected light or other lights which does not come from a light source) is totally reflected in the sixth insulating layer 130 via this design, to block the stray light from passing through the sixth insulating layer 130. In different embodiments, it also may have the same technical feature without departing from the spirit of the present disclosure.

In addition, the first bottom width WB1 may be smaller to the second bottom width WB2, and the second bottom width WB2 may be equal to the second top width WT2. That is, the entire (e.g., the top and the bottom) widths of the second opening 132 are equal, and the second bottom width WB2 may be greater than the first bottom width WB1, such that the width of the opening close to the substrate 100 is smaller, which may absorb or reflect more stray lights in different paths. In some embodiments, the light-shielding layer 120 may be opened first to form the first opening 122, then, the sixth insulating layer 130 and the light-collecting element 140 may be disposed on the light-shielding layer 120. In some embodiments, the second bottom width WB2 may be smaller than the second top width WT2.

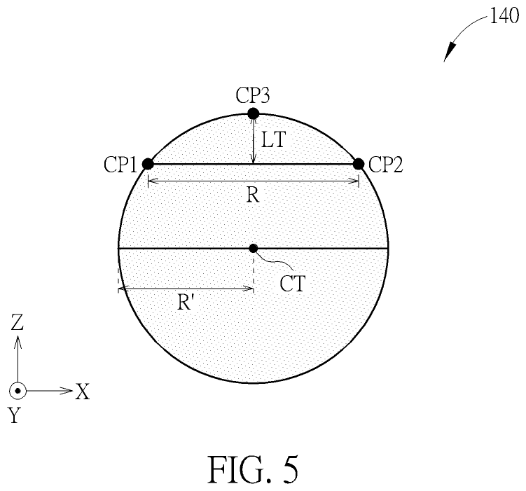

FIG. 5 is a schematic diagram of the light-collecting element 140 for calculating a radius of curvature of a spherical mirror according to some embodiments of the present disclosure. As shown in FIG. 5, X axis, Y axis and Z axis are perpendicular to each other, wherein the Z axis is the normal direction of the substrate 100. Please refer to both FIG. 4 and FIG. 5, in a cross-sectional direction, a radius R′ of curvature of a spherical mirror of the light-collecting element 140 may be obtained (e.g., calculated) according to a distance between two end points CP1 and CP2 of the light-collecting element 140 contacting the top of the sixth insulating layer 130.

For example, a chord R of the light-collecting element 140 may be the shortest distance between the two endpoints CP1 and CP2 according to a contacting surface (e.g., circle) of the light-collecting element 140 contacting the spherical mirror and the top of the sixth insulating layer 130. The chord R of the light-collecting element 140 may be obtained (e.g., calculated). Along the Z axis, a first thickness LT may be obtained (e.g., calculated) according to the shortest distance between an end point CP3 of the light-collecting element 140 which is the farthest from the top of the sixth insulating layer 130 and the top of the sixth insulating layer 130 (e.g., a point on a virtual surface formed by an extension of the top of the sixth insulating layer 130 or a point on a straight line formed by the two endpoints CP1 and CP2, e.g., the dotted-line in FIG. 4), wherein measurement directions of the chord R and the first thickness LT are perpendicular to each other. Then, the radius R′ of curvature of the spherical mirror may be realized according to equation (1):

R′²=((½)R)²+(R′−LT)² (1)

The radius R′ of curvature of the spherical mirror of the light-collecting element 140 may be obtained (e.g., calculated) according to a distance between two ends of a straight line passing through a center CT of the spherical mirror in the light-collecting element 140. For example, the radius R′ of curvature of the spherical mirror may be half of the distance between the two ends of the straight line passing through the center CT in the light-collecting element 140.

In addition, as shown in FIG. 4 and FIG. 5, along the Z axis, a focus distance F may be obtained (e.g., calculated) according to the shortest distance between the end point CP3 of the light-collecting element 140 which is the farthest from the top of the sixth insulating layer 130 and the top of the light-sensing element 112 (e.g., the top of a third semiconductor layer 1122). In some embodiment, a relationship between the first refractive index N1, the third refractive index N3, the focus distance F and the radius R′ of curvature of the spherical mirror may be realized according to equation (2):

N1/N3=F/(F−R′) (2)

In some embodiments, along the Z axis, a second thickness OT may be a distance between the top of the sixth insulating layer 130 and the bottom of the sixth insulating layer 130 when the focus distance F of the light-collecting element 140 is designed to be close to the light-sensing element 112. Along the Z axis, a fourth thickness ST may be a distance between the top of the light-shielding layer 120 and the bottom of the light-shielding layer 120. Along the Z axis, a third thickness PT may be a distance between the bottom of the light-shielding layer 120 and the top of the light-sensing elements 112. A relationship between the first thickness LT, the second thickness OT, the third thickness PT and the fourth thickness ST may be realized according to equation (3):

OT=2R′−LT−PT−ST (3)

That is, the second thickness OT of the sixth insulating layer 130 may be determined according to the radius R′ of curvature of the spherical mirror, the first thickness LT of the light-collecting element 140, the third thickness PT between the bottom of the light-shielding layer 120 and the top of the light-sensing elements 112 and the fourth thickness ST of the light-shielding layer 120.

In some embodiments, when the focus distance F of the light-collecting element 140 is designed to be close to the light-shielding layer 120, the third thickness PT may not be considered and the second thickness OT may be realized according to equation (4):

OT=2R′−LT−ST (4)

In addition, as shown in FIG. 5, the radius R′ of curvature of the spherical mirror may be obtained (e.g., calculated) according to the chord R and the first thickness LT. In some embodiments, the radius R′ of curvature of the spherical mirror may be 9-9.5 micrometer (μm), the first thickness LT may be 4-4.5 μm, the third thickness PT may be 2-2.5 μm, and the second thickness OT may be 12 μm. The above values are only an embodiment of the present disclosure, but is not limited thereto.

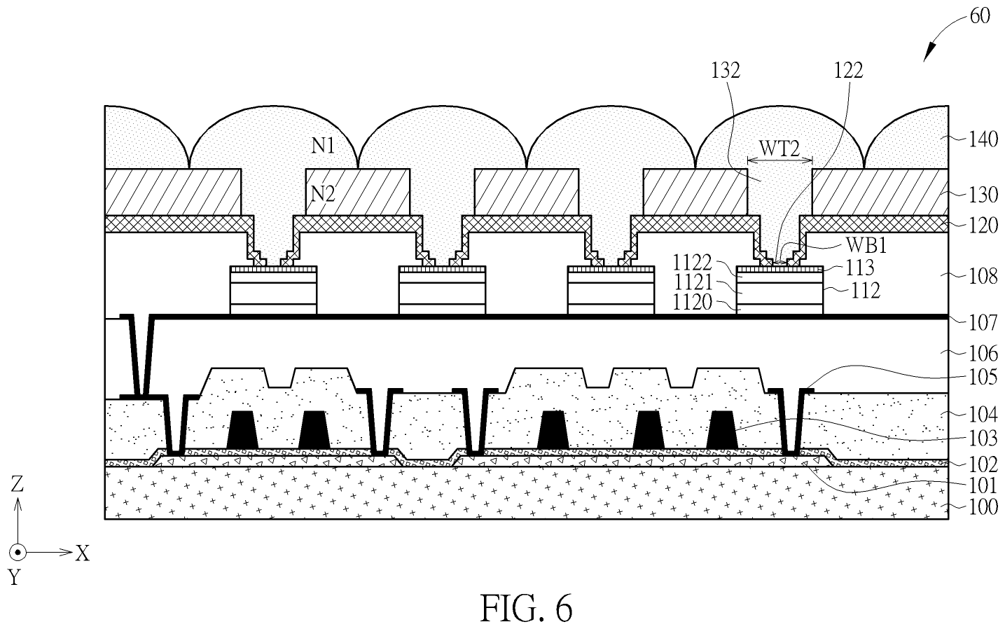

FIG. 6 is a schematic diagram of an optical sensing device 60 according to some embodiments of the present disclosure. Compared with the optical sensing device 10 in FIG. 1, the optical sensing device 60 may not include the light-shielding element 134. In addition, compared with the optical sensing device 40 in FIG. 4, the light-shielding layer 120 may be conductive, which may replace the fourth conductive layer 109, and may be electrically connected to the light-sensing element 112. The light-shielding layer 120 may include a conductive material (e.g., metal, but is not limited thereto), and may be electrically connected to the light-sensing element 112 via the fifth conductive layer 113. That is, the light-sensing element 112 is controlled via the light-shielding layer 120 and/or the fifth conductive layer 113, and a stray light (e.g., a reflected light or other lights which does not come from a light source) is reflected via the light-shielding layer 120 and/or the fifth conductive layer 113, to block interference of the stray light. In this embodiment, the first bottom width WB1 of the first opening 122 may be smaller than the second top width WT2 of the second opening 132. This design may absorb or reflect more stray lights in different paths. In different embodiments, it also may have the same technical feature without departing from the spirit of the present disclosure.

The following embodiments may be used in various figures in the present disclosure.

In some embodiments, the optical sensing device 10-50 may be an electronic device including the light-sensing element 112, but is not limited thereto. The optical sensing device 10 may include a display device, an antenna device, a sensing device, or a splicing device, but is not limited thereto. The electronic device may be a bendable electronic device or a flexible electronic device. The electronic device may include, for example, a liquid crystal light emitting diode (LED). The light emitting diode may include, for example, an organic LED (OLED), a sub-millimeter LED (mini LED), a micro LED or a quantum dot LED (quantum dot (QD), e.g., QLED, QDLED), fluorescence, phosphor, or other suitable materials. The materials may be arranged and combined arbitrarily, but is not limited thereto. The antenna device may be, for example, a liquid antenna, but is not limited thereto. The splicing device may be, for example, a display splicing device or an antenna splicing device, but is not limited thereto. It is noted that, the electronic device may be arranged and combined arbitrarily, but is not limited thereto.

In some embodiments, the substrate 100 may include a rigid substrate, a flexible substrate or combination thereof, but is not limited thereto. For example, the substrate 100 may include glass, quartz, sapphire, acrylic resin, polycarbonate (PC), polyimide (PI), polyethylene terephthalate (PET), other suitable transparent materials or combination thereof, but is not limited thereto.

In some embodiments, the light (not shown in the above figures) may be disposed adjacent to the substrate 100, e.g., under the substrate 100 or on a side of the substrate 100. In some embodiments, the light may include a direct type backlight unit (BLU), a side-light type BLU or a self-luminous BLU or other suitable transparent BLUs, but is not limited thereto.

A material of the first semiconductor layer 101 may be a low temperature polysilicon (LTPS), a low temperature polysilicon oxide (LTPO) or an amorphous silicon (a-Si), but is not limited thereto. In some embodiments, the TFT may include, for example, a top gate type TFT, but is not limited thereto. In other embodiments, the TFT may include, for example, a bottom gate type TFT or a double gate (dual gate) type TFT.

In some embodiments, the first conductive layer 103, the second conductive layer 105, the third conductive layer 107, the fourth conductive layer 109 or the fifth conductive layer 113 may include a transparent conductive material, e.g., transparent conducting oxide (TCO), indium tin oxide (ITO) or Indium doped zinc oxide, but is not limited thereto. In some embodiments, the first conductive layer 103, the second conductive layer 105, the third conductive layer 107, the fourth conductive layer 109 or the fifth conductive layer 113 may include a non-transparent conductive material, e.g., metal, metal oxide, other suitable conductive materials or combinations thereof, but is not limited thereto. The metal may include Aluminum, Copper, Silver, Chromium, Titanium, Molybdenum, other suitable materials or combinations thereof, but is not limited thereto.

In some embodiments, a buffer may be disposed between the substrate 100 and the first semiconductor layer 101. A material of the buffer may include an organic material, an inorganic material, other suitable transparent materials or combination thereof, but is not limited thereto. The inorganic material may include silicon nitride, silica, silicon oxynitride, Alumina (Al₂O₃), Hafnium oxide (HfO2), other suitable materials or combination thereof, but is not limited thereto. The organic material may include epoxy resins, silicone, acrylic resins (e.g., polymethylmetacrylate (PMMA)), polyimide, perfluoroalkoxy alkane (PFA), other suitable materials or combination thereof, but is not limited thereto.

In some embodiments, the first insulating layer 102 may include a gate insulator (GI), but is not limited thereto. In some embodiments, the second insulating layer 104 may include an interlayer dielectric (ILD), but is not limited thereto. In some embodiments, the third insulating layer 106, the fourth insulating layer 108, the fifth insulating layer 110 or the sixth insulating layer 130 may be an over coat (OC), but is not limited thereto. In some embodiments, the third insulating layer 106, the fourth insulating layer 108, the fifth insulating layer 110 or the sixth insulating layer 130 may include the above organic material, the above inorganic material and silicon nitride, silica, silicon oxynitride, other suitable materials or combination thereof, but is not limited thereto.

In some embodiments, the light-sensing element 112 may include a photodiode, a photoconductor or a phototransistor, but is not limited thereto. In some embodiments, the photodiode may include a second semiconductor layer 1120, an intrinsic semiconductor layer 1121 and the third semiconductor layer 1122 disposed along the Z axis, wherein the intrinsic semiconductor layer 1121 may be disposed (e.g., sandwiched) between the second semiconductor layer 1120 and the third semiconductor layer 1122. In some embodiments, the second semiconductor layer 1120 and the intrinsic semiconductor layer 1121 may include different materials. That is, the light-sensing element 112 may include a PIN diode or a NIP diode, but is not limited thereto. In some embodiments, the photoconductor may include a metal semiconductor metal (MSM). In some embodiments, the phototransistor may include a semiconductor layer or a conductive layer.

In some embodiments, the light-collecting element 140 may include a lens, but is not limited thereto.

In some embodiments, the light-shielding element 134 may include the light-absorbent material. In some embodiments, the light-shielding element 134 may include the reflecting material. In some embodiments, the light-absorbent material may include a resin, a black matrix (BM), a photoresist, a carbon black material, a resin type material, other suitable materials or combination thereof, but is not limited thereto. In some embodiments, the reflecting material may include a metal, e.g., Molybdenum, Copper, Nickel, Aluminum, Titanium, other suitable materials or combination thereof, but is not limited thereto.

It is noted that, for purposes of illustrative clarity and being easily understood by the readers, various drawings of this disclosure label a portion of the same elements, layers or openings in this disclosure. For example, the elements illustrated with hexagonal patterns are all the light-sensing elements 112, the film layers illustrated with grids are all the light-shielding layers 120, the films illustrated with diagonal stripes from an upper right to a lower left are all the sixth insulating layers 130, the elements illustrated with diagonal stripes from an upper left to a lower right are all the light-shielding elements 134, and the elements illustrated with dotted-patterns are all the light-collecting elements 140.

It will be understood that, when the element is referred to “in the layer” or “in the opening”, it may be directly in this layer or in this opening, or other element(s) may exist between them (indirect case).

It is noted that, the technical features in above embodiments can be replaced, recombined or mixed with one another to constitute another embodiment without departing from the spirit of the present disclosure.

To sum up, in the optical sensing device of the present disclosure, a structure formed via the light-shielding element, the insulating layer and the light-shielding layer or a structure formed via the light-shielding element and the insulating layer may reduce material costs, may simplified complicated manufacturing processes or may improve a noise ratio. As a result, the existing complicated manufacturing processes of the optical sensing device may be improved, and a quality of the optical sensing device may also be improved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An optical sensing device, comprising:
a substrate;
a light-sensing element disposed on the substrate;
a light-shielding layer disposed on the light-sensing element, comprising a first opening overlapping the light-sensing element;
an insulating layer disposed on the light-shielding layer, comprising a second opening overlapping the first opening;
a light-shielding element disposed on a hole wall of the second opening; and
a light-collecting element disposed on the insulating layer and overlapping the second opening.

2. The optical sensing device of claim 1, wherein the light-shielding element comprises a light-absorbent material.

3. The optical sensing device of claim 1, wherein the light-shielding element comprises a reflecting material.

4. The optical sensing device of claim 1, wherein the light-shielding layer and the light-shielding element comprises the same material.

5. The optical sensing device of claim 1, wherein the light-shielding layer and the light-shielding element comprises different materials.

6. The optical sensing device of claim 1, wherein at least one part of the light-collecting element is located in the second opening.

7. The optical sensing device of claim 1, wherein the first opening has a first bottom width and the second opening has a second bottom width in a cross-sectional direction, and the first bottom width is smaller than the second bottom width.

8. The optical sensing device of claim 1, wherein the second opening has a second bottom width and the second opening has a second top width in a cross-sectional direction, and the second bottom width is smaller than the second top width.

9. An optical sensing device, comprising:
a substrate;
a light-sensing element disposed on the substrate;
a light-shielding layer disposed on the light-sensing element, comprising a first opening overlapping the light-sensing element;
an insulating layer disposed on the light-shielding layer, comprising a second opening overlapping the first opening; and
a light-collecting element disposed on the insulating layer, and at least one part of the light-collecting element is located in the second opening;
wherein a first refractive index of the insulating layer is greater than a second refractive index of the light-collecting element.

10. The optical sensing device of claim 9, wherein the first opening has a first bottom width and the second opening has a second bottom width in a cross-sectional direction, and the first bottom width is smaller than the second bottom width.

11. The optical sensing device of claim 9, wherein the second opening has a second bottom width and the second opening has a second top width in a cross-sectional direction, and the second bottom width is smaller than the second top width.

12. The optical sensing device of claim 9, wherein the light-shielding layer is electrically connected to the light-sensing element.
